(19) United States
(12) Patent Application Publication
(10) Pub. No.: US 2003/0132520 A1
(43) Pub. Date: Jul. 17, 2003

(54) Semiconductor device and mounting method

(76) Inventors: Masako Watanabe, Oita (JP); Kazuaki Ano, Oita (JP); Masazumi Amagai, Oita (JP)

Correspondence Address: TEXAS INSTRUMENTS INCORPORATED, P O BOX 655474, M/S 3999, DALLAS, TX, 75265

(21) Appl. No.: 10/341,140

(22) Filed: Jan. 13, 2003

(30) Foreign Application Priority Data
Jan. 11, 2002 (JP) 2002-004654

(51) Int. Cl. H01L 23/48

(52) U.S. Cl. 257/738

(57) ABSTRACT

A semiconductor device (100) has a semiconductor chip (102) mounted on a tape carrier (104). Tape carrier (104) of thickness t has a plurality of via holes (118) of inner diameter Dᵥ penetrating the tape carrier (104). Solder balls (114) having outer diameter D_{b} are attached through the via holes (118) to serve as external connection terminals for the semiconductor chip (102). Specific dimensional relationships are established among thickness t of tape carrier (104), inner diameter Dᵥ of via holes (118) and outer diameter D_{b} of solder balls (114) in order to improve connection reliability by reducing poor connections of solder balls (114).

### FIELD OF THE INVENTION

The present invention relates generally to a semiconductor device and method for mounting said semiconductor device onto a circuit board; and, in particular, to improvements in electrical connection between said device and said circuit board.

### BACKGROUND OF THE INVENTION

In recent years, BGA (Ball Grid Array) structures utilizing solder balls serving as external terminals have drawn attention where semiconductor packages need to be miniaturized and provided with many pins. In the case of a semiconductor package with the BGA structure, a semiconductor chip is mounted on a first surface of a chip mounting substrate (such as, for example, a tape carrier), and solder balls are attached to an opposing second surface through via holes penetrating the substrate from the first to the second surfaces. A conductor pattern is formed on the first surface of the chip mounting substrate in order to achieve electrical connection with electrode pads of the semiconductor chip. The solder balls are joined to parts (land parts) of the conductor pattern via solder paste filling the via hole.

During mounting of the semiconductor package onto a circuit board, electrical connection between the semiconductor package and the circuit board is secured by joining (soldering) the solder balls of the semiconductor package to corresponding terminal parts of the circuit board.

The degree and quality of attachment of the solder balls may be negatively affected by a variety of conditions. Thus, when a solder ball is joined to the terminal part of the circuit board (or during a subsequent tolerance test), the solder ball may be pulled toward the circuit board and separated from the land part, resulting in poor connection. There is a need to reduce such solder ball connection problems and improve reliability of the connection.

### SUMMARY OF THE INVENTION

In accordance with one aspect of the invention, a semiconductor device is provided that has a semiconductor chip and a chip mounting substrate having first and second opposing surfaces. The chip mounting substrate is formed with via holes penetrating between the first and second surfaces and the semiconductor chip is mounted on the first surface in electrical communication with the via holes. The chip mounting substrate has a thickness t mm between the surfaces at the via holes and the via holes have an inner diameter Dᵥ mm. The chip mounting substrate thickness and via holes are relatively dimensioned according to the following relationship:

Dᵥ−3.75×t+0.095>0. (1)

In accordance with another aspect of the invention, conductive balls of outer diameter D_{b} mm are attached at the second surface of the chip mounting substrate through the via holes to serve as external electrical connection terminals for the semiconductor chip. In one embodiment having a chip carrier thickness of 0.05 mm, the via holes and conductive balls are relatively dimensioned according to the following relationship:

Dᵥ−0.4×D_{b}−0.17>0. (2)

In another embodiment having a chip carrier thickness of 0.075 mm, the via holes and conductive balls are relatively dimensioned according to the following relationship:

Dᵥ−1.5×D_{b}+0.28>0. (3)

The chip mounting substrate may advantageously be a tape carrier.

In another aspect of the invention, a method is provided for mounting a semiconductor device onto a circuit board or similar conductive patterned substrate. Conductive balls are employed within vias of a chip mounting substrate of the semiconductor device to electrically connect a semiconductor chip mounted on the chip mounting substrate with corresponding portions of the conductive pattern of the circuit board. Dimensional relationship are established in accordance with one or more of the Equations (1)-(3) among a thickness t mm of the chip mounting substrate, an inner diameter Dᵥ of the via holes, and an outer diameter of D_{b} of the conductive balls.

### BRIEF DESCRIPTION OF THE DRAWINGS

FIG. 1 is a partial cut-away perspective view showing the structure of an embodiment of a type of semiconductor device package within which the principles of the invention may be applied.

FIG. 2 is an enlarged cross section view of a portion of the device of FIG. 1 shown mounted on a circuit board.

FIGS. 3A and 3B are views similar to the view of FIG. 2, helpful to illustrate the occurrence of separation of a solder ball from a semiconductor package of the type shown in FIG. 1.

FIG. 4 is a graph showing the relationships among the inner diameter of the via hole, the outer diameter of the solder ball, and the presence/absence of poor connections.

FIG. 5 is a graph showing the relationships among the inner diameter of the via hole, the thickness of the tape carrier, and the presence/absence of poor connections.

### DETAILED DESCRIPTION OF EMBODIMENTS

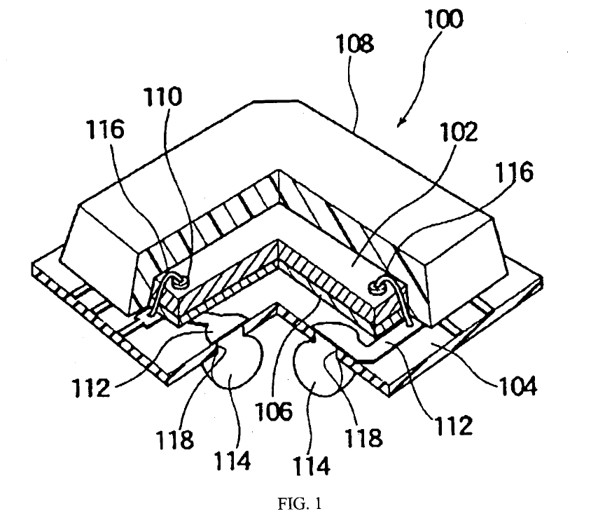

Illustrative embodiments of the invention are described in the context of an example of a BGA semiconductor device shown in FIG. 1.

As shown in FIG. 1, a semiconductor device 100 has a semiconductor chip 102 attached to a first surface (upper surface in FIG. 1) of a chip mounting substrate, such as a tape carrier 104, using die paste 106. Semiconductor chip 102 is encapsulated using a sealant 108 made of a resin. Semiconductor chip 102 is created by forming an integrated circuit, not illustrated, on a primary surface (upper surface in FIG. 1) of a silicon substrate. A plurality of electrode pads 110 leading out from the integrated circuit may be arranged at an outer periphery of the surface of semiconductor chip 102 where the integrated circuit is formed.

Tape carrier 104 is a tape-like member made of an insulating material, such as polyimide. A conductor pattern 112 made of copper (Cu) is formed on the first surface of tape carrier 104, and the conductor pattern 112 is connected to electrode pads 110 of semiconductor chip 102 via conductive wires 116. Conductive balls, such as solder balls 114, are attached at a second surface (lower surface in FIG. 1) of tape carrier 104 to serve as external electrical connection terminals for the conductive pattern 112 (and, thus, for the semiconductor chip 102). Solder balls 114 are formed and attached using a solder paste (paste-like mixture of solder powders, organic resin components, and flux) in via holes 118 formed in tape carrier 104 to intersect parts of the conductor pattern 112.

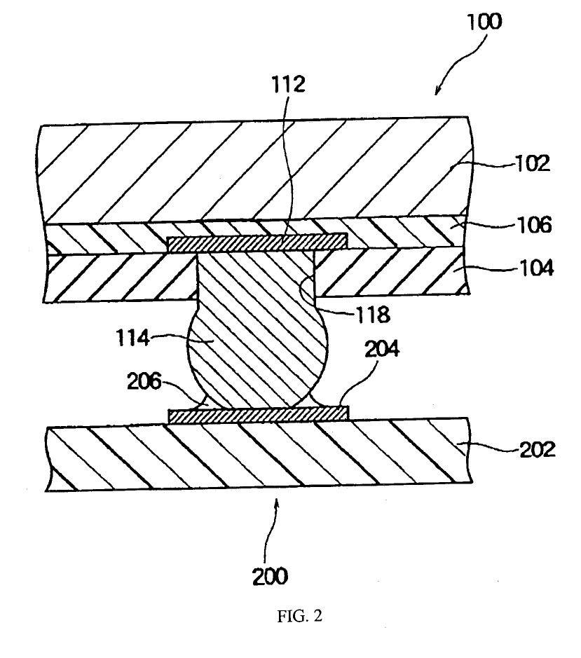

FIG. 2 is a cross section view showing a peripheral part of a solder ball 114 when semiconductor package 100 is mounted onto a circuit board 200. Circuit board 200 has terminal parts 204 made of Cu formed on a surface of a substrate 202 made of a resin. Terminal part 204 is formed to correspond to a position of a solder ball 114 of semiconductor package 100.

When solder ball 114 is attached to semiconductor package 100, a solder paste may be predeposited into via hole 118 of tape carrier 104, and a reflow process (process for fluidizing solder ball 114 and the solder paste) may be performed to join solder ball 114 to conductor pattern 112 (using the solder paste).

When mounting semiconductor package 100 onto circuit board 200, after solder paste 206 has been supplied to the surface of terminal part 204, a reflow process is performed in order to join solder ball 114 to terminal part 204. As a result, conductor pattern 112 in semiconductor package 100 and terminal part 204 of circuit board 200 are electrically connected.

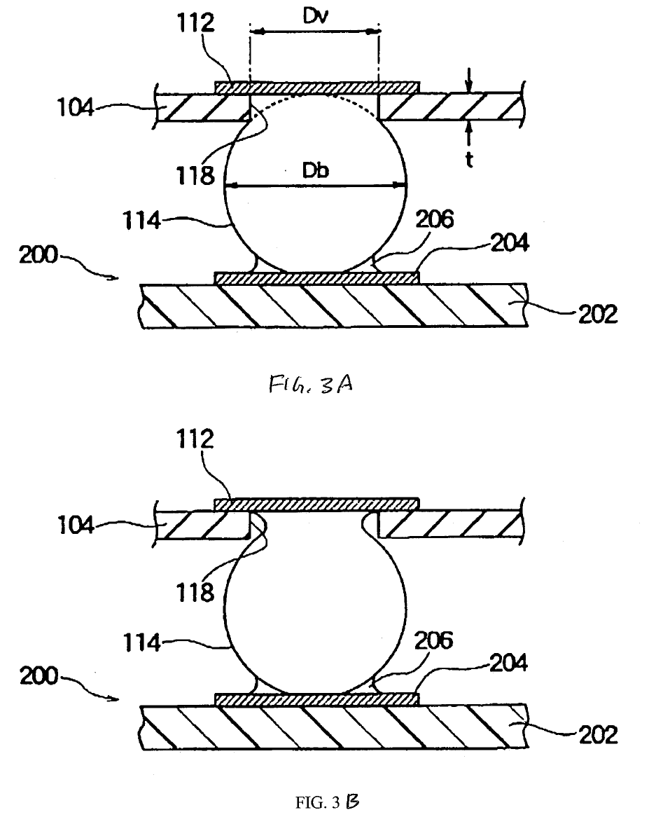

FIGS. 3A and 3B illustrate a separation of a solder ball like solder ball 114, of a type which could occur during a tolerance test performed after a semiconductor package like package 100 has been mounted onto a conductive patterned substrate like circuit board 200. In general, as shown in FIGS. 3A and 3B, it is possible for a solder ball 114 to pull together in via hole 118 as it is sucked toward circuit board 200, and ultimately to separate from conductor pattern 112 (that is, poor connection occurs), depending on how it is attached.

In order to prevent this kind of poor connection, the relative dimensions (viz., in mm) of the thickness t of tape carrier 104 at a via hole 118 and the inner diameter Dᵥ of the respective via hole 118 are relatively established in semiconductor device embodiments of the invention in accordance with the following relationship:

Dᵥ−3.75×t+0.095>0. (1)

Furthermore, to further prevent poor connections, the relative dimensions (viz., in mm) of the inner diameter Dᵥ of a via hole 118 and the outer diameter D_{b} of the respective conductive ball 114 are relatively established in such embodiments in accordance with the relationships given below.

When thickness t of tape carrier 104 is 0.05 mm:

Dᵥ−0.4×D_{b}−0.17>0. (2)

When thickness t of tape carrier 104 is 0.075 mm:

Dᵥ−1.5×D_{b}+0.28>0. (3)

The basis for establishing the relationships expressed in Equations (1) through (3) is given below.

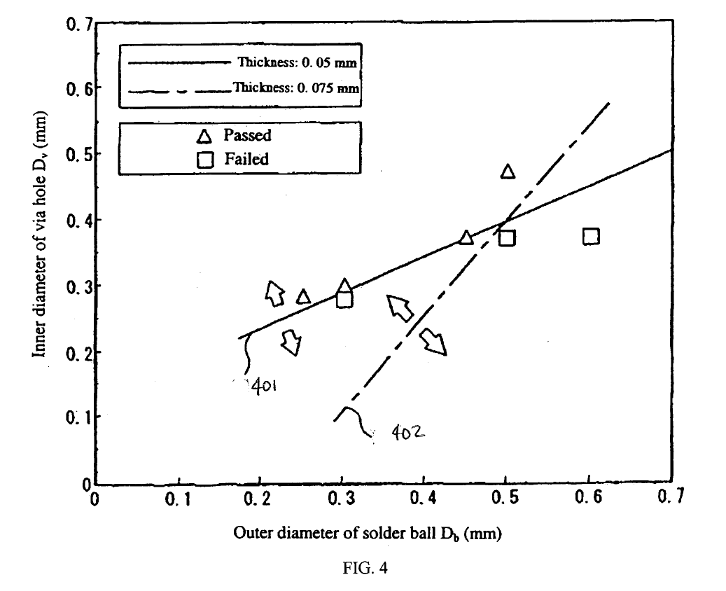

The relationships among inner diameter Dᵥ of via hole 118, outer diameter D_{b} of solder ball 114, and the presence/absence of a poor connection are shown in FIG. 4. Here, various kinds of semiconductor packages 100 were created by varying outer diameter D_{b} of solder ball 114 and inner diameter Dᵥ of via hole 118, the semiconductor packages 100 were respectively mounted onto a circuit board 200, and tolerance tests were carried out. The thickness of tape carriers 104 of semiconductor packages 100 was fixed at 0.05 mm. The material used as the material for solder ball 114 was SnPbAg (Sn: 62 weight %; Pb: 36 weight %; Ag: 2 weight %). As the tolerance test, a moisture absorption step (30° C., 85% moisture) and an infrared radiation reflow step were repeated for two cycles, and the presence/absence of a poor connection was checked.

In FIG. 4, a triangle mark indicates a passed condition (no poor connection occurred during the tolerance test), and a rectangle mark indicates a failed condition (a poor connection occurred during the tolerance test). When the boundary between the area expressed by the collection of these triangular marks and the area expressed by the square marks is obtained by means of a least squares method, straight line 401, expressed by Equation (4), below, can be obtained:

Dᵥ−0.4×D_{b}−0.17=0. (4)

In FIG. 4, the region above straight line 401 is a region where no poor connection occurs, as is made clear by the fact that triangular marks are present therein. On the other hand, the region below straight line 401 is a region where poor connections occur, as is made clear by the fact that square marks are present therein. When the region where no poor connections occur (that is, the region above straight line 401) is expressed in the form of an inequality, the relationship set forth in Equation (2) emerges. That is, when thickness t of tape carrier 104 is 0.05 mm, the occurrence of poor connections can be reduced by selecting inner diameter Dᵥ of via hole 118 and outer diameter D_{b} of solder ball 114 so as to satisfy the relationship expressed in Equation (2).

Similarly, when thickness t of tape carrier 104 is 0.075 mm, the boundary between the region where no poor connection occurs and the region where poor connections occur can be shown as straight line 402, expressed by Equation (5), below. Furthermore, triangular marks and square marks are omitted with reference to the case in which thickness t is set to 0.075 mm.

Dᵥ−1.5×D_{b}+0.28=0. (5)

As with straight line 401, the region above straight line 402 is a region where no poor connection occurs, and the region below straight line 402 is a region where poor connections occur. When the region where no poor connections occur (region above straight line 402 is expressed in the form of an inequality, the relationship set forth in Equation (3) emerges. That is, when thickness t of tape carrier 104 is 0.075 mm, the occurrence of poor connections can be reduced by selecting inner diameter Dᵥ of via hole 118 and outer diameter D_{b} of solder ball 114 so as to satisfy the relationship expressed in Equation (3).

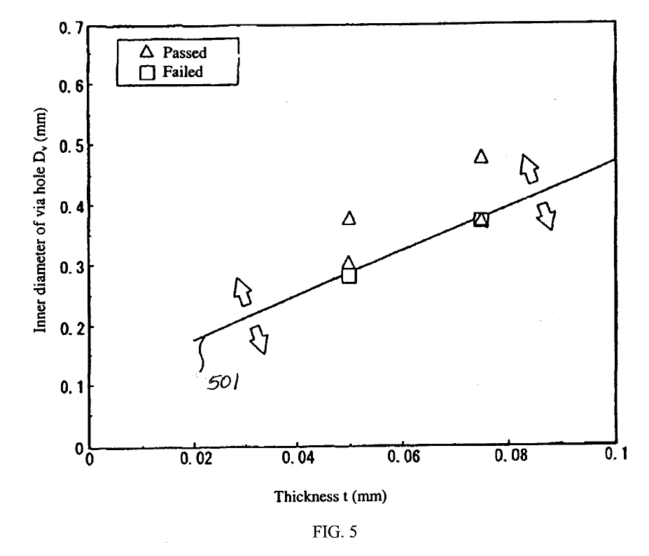

The relationships among inner diameter Dᵥ of via hole 118, thickness t of tape carrier 104, and the presence/absence of a poor connection are shown in FIG. 5. As in FIG. 4, a triangle mark indicates a passed condition (no poor connection occurred during the tolerance test), and a rectangle mark indicates a failed condition (a poor connection occurred during the tolerance test). When the boundary between the region expressed by the collection of these triangular marks and the region expressed by the collection of the square marks is obtained by means of a least squares method, straight line 501, expressed by Equation (6), below, can be obtained:

Dᵥ−3.75×t+0.095=0. (6)

In FIG. 5, the region above straight line 501 is a region where no poor connection occurs, and the region below straight line 501 is a region where poor connections occur. When the region where no poor connection occurs (region above straight line 501) is expressed in the form of an inequality, the relationship expressed in Equation (1) emerges. That is, the occurrence of poor connections can be reduced, regardless of the outer diameter of solder ball 114, by selecting inner diameter Dᵥ of via hole 118 and thickness t of tape carrier 104 so as to satisfy the relationship set forth in Equation (1).

As described above, in the present embodiment, occurrences of poor connection can be reduced by optimizing inner diameter Dᵥ of via hole 118, thickness t of tape carrier 104, and outer diameter D_{b} of solder ball 114 using Equation (1) through (3). As a result, the occurrence of poor electrical connections in circuit board 200 having semiconductor package 100 mounted thereon can be prevented.

As described above, because Equation (1) is established between inner diameter Dᵥ of the via hole and thickness t of the chip mounting substrate in the present invention, poor connection of the solder ball can be prevented, so that the connection reliability can be improved. Therefore, the occurrence of poor electrical connections in the circuit board having the semiconductor package mounted on it can be prevented.

In particular, poor connections of the solder balls can be prevented more reliably by establishing Equation (2) when thickness t of the chip mounting substrate is 0.05 mm, and Equation (3) when thickness t of the chip mounting substrate is 0.075 mm.

Embodiments of the invention have been described with reference to the accompanying figures, in the context of a semiconductor device of the BGA type and the mounting of that device onto a circuit board as shown. However, the present invention is not limited to such device type or the described embodiments. For example, a semiconductor chip mounting substrate other than tape carrier 104 can be used.

Those skilled in the art to which the invention relates will appreciate that various substitutions and modifications may be made to those embodiments, without departing from the spirit and scope of the invention as set forth in the description and the claims.

1. A semiconductor device comprising:
a semiconductor chip; and
a chip mounting substrate having first and second opposing surfaces, and via holes for penetrating between said first and second surfaces;
said semiconductor chip being mounted on said first surface in electrical connection with said via holes; said chip mounting substrate having a thickness t between said surfaces at said via holes; said via holes having an inner diameter Dᵥ; and said thickness and via holes being relatively dimensioned according to the following relationship:
Dᵥ−3.75×t+0.095>0.

2. A semiconductor device as in claim 1, further comprising conductive balls attached at said second surface through said via holes to serve as external electrical connection terminals for said semiconductor chip.

3. A semiconductor device as in claim 2, wherein said conductive balls have an outer diameter D_{b} mm; wherein said thickness t is 0.05 mm; and wherein said via holes and conductive balls are relatively dimensioned according to the following relationship:
Dᵥ−0.4×D_{b}−0.17 >0.

4. A semiconductor device as in claim 3, wherein said conductive balls comprise solder balls.

5. A semiconductor device as in claim 4, where said semiconductor device is a ball grid array semiconductor package, and said chip mounting substrate comprises a tape carrier.

6. A semiconductor device as in claim 2, wherein said conductive balls have an outer diameter D_{b} mm; wherein said thickness t is 0.075 mm; and wherein said via holes and conductive balls are relatively dimensioned according to the following relationship:
Dᵥ−1.5×D_{b}+0.28 >0.

7. A semiconductor device as in claim 6, wherein said conductive balls comprise solder balls.

8. A semiconductor device as in claim 7, where said semiconductor device is a ball grid array semiconductor package, and said chip mounting substrate comprises a tape carrier.

9. A method for providing a semiconductor device having conductive balls thereon, comprising:
providing a semiconductor device including a semiconductor chip mounted on a first surface of a chip mounting substrate in electrical connection with via holes penetrating said chip mounting substrate between said first surface and an opposing second surface; and
establishing conductive balls at said second surface through said via holes to serve as external electrical connection terminals for said semiconductor chip;
said chip mounting substrate having a thickness t between said surfaces at said via holes;
said via holes having an inner diameter Dᵥ; and said thickness and via holes being relatively dimensioned according to the following relationship:
Dᵥ−3.75×t+0.095 >0.

10. A method as in claim 9, wherein said inner diameter is an inner diameter Dᵥ mm; said conductive balls have an outer diameter D_{b} mm; said thickness t is 0.05 mm; and said via holes and conductive balls are relatively dimensioned according to the following relationship:
Dᵥ−0.4×D_{b}−0.17>0.

11. A method as in claim 9, wherein said inner diameter is an inner diameter Dᵥ mm; said conductive balls have an outer diameter D_{b} mm; said thickness t is 0.075 mm; and said via holes and conductive balls are relatively dimensioned according to the following relationship:
Dᵥ−1.5×D_{b}+0.28>0.

12. A method for mounting a semiconductor device onto a circuit board, comprising:
providing a semiconductor device including a semiconductor chip mounted on a first surface of a chip mounting substrate in electrical connection with via holes penetrating said chip mounting substrate between said first surface and an opposing second surface;
providing conductive balls at said second surface through said via holes to serve as external electrical connection terminals for said semiconductor chip; and
joining said conductive balls to corresponding terminal parts of said circuit board to establish electrical connection between said semiconductor chip and said terminal parts through said vias and conductive balls;
said chip mounting substrate having a thickness t between said surfaces at said via holes; said via holes having an inner diameter Dᵥ; and said thickness and via holes being relatively dimensioned according to the following relationship:
Dᵥ−3.75×t+0.095>0.

13. A method as in claim 12, wherein said inner diameter is an inner diameter Dᵥ mm; said conductive balls have an outer diameter D_{b} mm; said thickness t is 0.05 mm; and said via holes and conductive balls are relatively dimensioned according to the following relationship:
Dᵥ−0.4×D_{b}−0.17>0.

14. A method as in claim 12, wherein said inner diameter is an inner diameter Dᵥ mm; said conductive balls have an outer diameter D_{b} mm; said thickness t is 0.075 mm; and said via holes and conductive balls are relatively dimensioned according to the following relationship:
Dᵥ−1.5×D_{b}+0.28>0.
